(19) United States
(12) Patent Application Publication
(10) Pub. No.: US 2017/0183767 A1
(43) Pub. Date: Jun. 29, 2017

(54) Mask Plate for Laser Irradiation and Method of Laser Encapsulation Using the Same

(71) Applicant: BOE Technology Group Co., Ltd., Beijing (CN)

(72) Inventor: Rui Hong, Beijing (CN)

(73) Assignee: BOE Technology Group Co., Ltd., Beijing (CN)

(21) Appl. No.: 15/314,690

(22) PCT Filed: Apr. 8, 2016
(86) PCT No.: PCT/CN2016/078847

§ 371 Date: Nov. 29, 2016

(30) Foreign Application Priority Data
May 28, 2015 (CN) 201510284585.9

(51) Int. Cl. C23C 14/04; H01L 51/56; H01L 51/52; C23C 14/58

(52) U.S. Cl. CPC C23C 14/042; C23C 14/58; H01L 51/56; H01L 51/5246

(57) ABSTRACT

A mask plate for laser irradiation and a method of laser encapsulation using the same are disclosed to improve the display effect of the encapsulated display panel and also the utilization of substrate thereof, so as to reduce the cost. The mask plate includes a laser blocking region and a laser transmitting region surrounding the laser blocking region, wherein the laser blocking region is configured to block laser having a predetermined wavelength; and the laser transmitting region is configured to allow the laser having the predetermined wavelength to transmit there-through; along a direction perpendicular to a surface of the mask plate, a width of a cross-section of the laser transmitting region is smaller than a diameter of a light spot of the laser having the predetermined wavelength.

Embodiments of the present disclosure relates to a mask plate for laser irradiation and a method of laser encapsulation using the same.

### BACKGROUND

Performance of devices inside a manufactured display panel, such as OLED (Organic Light-Emitting Display) devices interior to an OLED display panel, is liable to be failed due to their easy reaction with water and oxygen in the air. Thus, the display panel is required to be encapsulated. As illustrated in FIG. 1, a known encapsulating process mainly includes: assembling a first substrate with a second substrate that are coated with a sealant to form a display panel to be encapsulated; irradiating the display panel to be encapsulated by laser which is emitted from a laser generator and transmitted through (in a direction indicated by the arrow of FIG. 1) a mask plate, so that the laser irradiates the sealant within an encapsulation region through a transmission region on the mask plate to melt the sealant by an energy of the laser beam; bonding the first substrate with the second substrate by using the melted sealant upon cooling, to form a sealed, encapsulating space inside the display panel, so as to complete the encapsulating process.

In the encapsulating process above, the energy of the laser beam is concentrated at a center of a light spot; consequently, in order to sufficiently irradiate the sealant, a width (indicated as d in FIG. 2) of an across section of the sealant coated on the encapsulating region is wider than a diameter φ of a light spot of the laser, as illustrated in FIG. 2. When the diameter φ of the light spot of the laser is larger than the width d of the cross section of the sealant, the laser will not only irradiate the sealant, but also will irradiate both sides of the sealant. The energy of the laser beam is extremely high with a transient temperature reaching 800° C.˜1000° C. Accordingly, for design of the display panel, in order to avoid the electronic devices inside the display panel to be burned by the energy generated from the laser beam, a safety area is usually reserved between the electronic devices and the encapsulating region (with a spacing of at least 0.7 mm). However, due to the limitation of the reserved safety area, it is difficult for the display panel to achieve narrow frame design, and meanwhile a utilization of the substrate may be reduced.

### SUMMARY

Embodiments of the disclosure provide a mask plate for laser irradiation and a method of laser encapsulation using the same, which can be applied in encapsulating a display panel with a narrow frame, improve display effect of the encapsulated display panel and meanwhile improve the utilization of the substrate to reduce the cost.

In order to achieve the above objective, the embodiments of the disclosure employ technical solutions as below.

In one aspect, the embodiments of the disclosure provide a mask plate for laser irradiation, the mask plate includes a laser blocking region and a laser transmitting region surrounding the laser blocking region, wherein the laser blocking region is configured to block laser having a predetermined wavelength; and the laser transmitting region is configured to allow laser having the predetermined wavelength to transmit therethrough, wherein, along a direction perpendicular to a surface of the mask plate, a width of a cross-section of the laser transmitting region is smaller than a diameter of a light spot of the laser having the predetermined wavelength.

In an example, upon placing the mask plate onto a panel to be encapsulated, the laser transmitting region corresponds to an encapsulating region of the panel to be encapsulated, and the laser blocking region corresponds to a device region surrounded by the encapsulating region of the panel to be encapsulated.

In an example, the mask plate includes plural laser blocking regions, and upon placing the mask plate onto the panel to be encapsulated, the plural laser blocking regions correspond to plural device regions arranged in an array on the panel to be encapsulated, and the laser transmitting region corresponds to a region other than the plural device regions.

In an example, the mask plate includes: a first main body, which is located at the laser transmitting region and is made of transparent material; and a second main body, which is located at the laser blocking region and has a diffusing surface.

In an example, a wavelength of the laser is 810 nm˜1000 nm; and a haze of the diffusing surface is 40%˜90%.

In an example, upon placing the mask plate onto the panel to be encapsulated, the diffusing surface of the second main body located at the laser blocking region is located at a side of the second main body far away from the panel to be encapsulated.

In an example, the mask plate includes: a first main body, which is located at the laser transmitting region and is made of transparent material; and a second main body, which is located at the laser blocking region and has a light absorbing layer as its surface.

In an example, upon placing the mask plate onto the panel to be encapsulated, the light absorbing layer of the second main body located at the laser blocking region is located on a side of the second main body far away from the panel to be encapsulated.

In an example, the transparent material includes any one of glass, quartz and acrylic.

In an example, the second main body and the first main body are formed integrally.

In an example, upon placing the mask plate onto the panel to be encapsulated, along a direction perpendicular to the surface of the mask plate, a width of the cross-section of the laser transmitting region is larger than or equal to the width of a cross-section of the encapsulating region.

In an example, upon placing the mask plate onto the panel to be encapsulated, along a direction perpendicular to the surface of the mask plate, the width of the cross-section of the laser transmitting region is larger than the width of the cross-section of the encapsulating region by 0.02 mm˜0.1 mm.

In an example, a thickness of the mask plate is 3 mm˜5 mm.

In another aspect, the embodiments of the disclosure further provide a method of laser encapsulation using the above described mask plate, including: placing the mask plate onto the panel to be encapsulated so that the laser blocking region corresponds to the device region of the panel to be encapsulated and the laser transmitting region corresponds to the encapsulating region of the panel to be encapsulated; and allowing the laser to transmit through the mask plate to irradiate a sealant in the encapsulating region of the panel to be encapsulated to cure the sealant.

In one example, the sealant is made of silicon sealant; and a wavelength of the laser is 810˜1000 nm.

Based on the foregoing technical solutions, when the above-described mask plate provided by the embodiments of the disclosure is applied in encapsulating the display panel, as a result of the width of the cross-section of the laser transmitting region of the mask plate being larger than or equal to the width of the cross-section of the encapsulating region of the panel to be encapsulated along the direction perpendicular to the mask plate, the sealant in the encapsulating region of the panel to be encapsulated can be sufficiently irradiated by the laser beam transmitted through the laser transmitting region, so as to ensure that the sealant can sufficiently absorb the energy and can be melted and cured, so that the encapsulating process of the panel to be encapsulated is completed. Furthermore, as a result of the width of the cross-section of the laser transmitting region of the mask plate being smaller than the diameter of a light spot of the laser along the direction perpendicular to the surface of the mask plate, the laser blocking region outside the laser transmitting region can block the laser which would irradiate the regions outside the encapsulating region of the panel to be encapsulated, so as to prevent the energy of the laser from being delivered to the electronic devices close to edges of the encapsulating region in the device region of the panel to be encapsulated. Therefore, for design of the panel to be encapsulated, the electronic devices in the device region can be arranged to be closer to the encapsulating region to achieve narrow frame and further improve the utilization of the substrate in the panel to be encapsulated.

### BRIEF DESCRIPTION OF THE DRAWINGS

Hereafter, the embodiments of the present disclosure will be described in a more detailed way with reference to the accompanying drawings, so as to make one person skilled in the art be able to understand the present disclosure more clearly, wherein:

FIG. 1 is a schematic diagram illustrating a working principle of an existing method of encapsulating a display panel with laser by using a mask plate;

FIG. 2 is a schematic diagram illustrating an enlarged structure of a part “a” in FIG. 1;

FIG. 3A is a first top view illustrating a structure of a mask plate provided by an embodiment of the disclosure;

FIG. 3B is a second top view illustrating a structure of the mask plate provided by the embodiment of the disclosure;

FIG. 4 is a first schematic diagram illustrating a cross-sectional structure along direction A-A′ in FIG. 3B;

FIG. 5A is a second schematic diagram illustrating a cross-sectional structure along direction A-A′ in FIG. 3B;

FIG. 5B is a third schematic diagram illustrating a cross-sectional structure along direction A-A′ in FIG. 3B; and

FIG. 6 is a transmittance-wavelength curve diagram illustrating laser irradiating a diffusing surface in FIG. 5A.

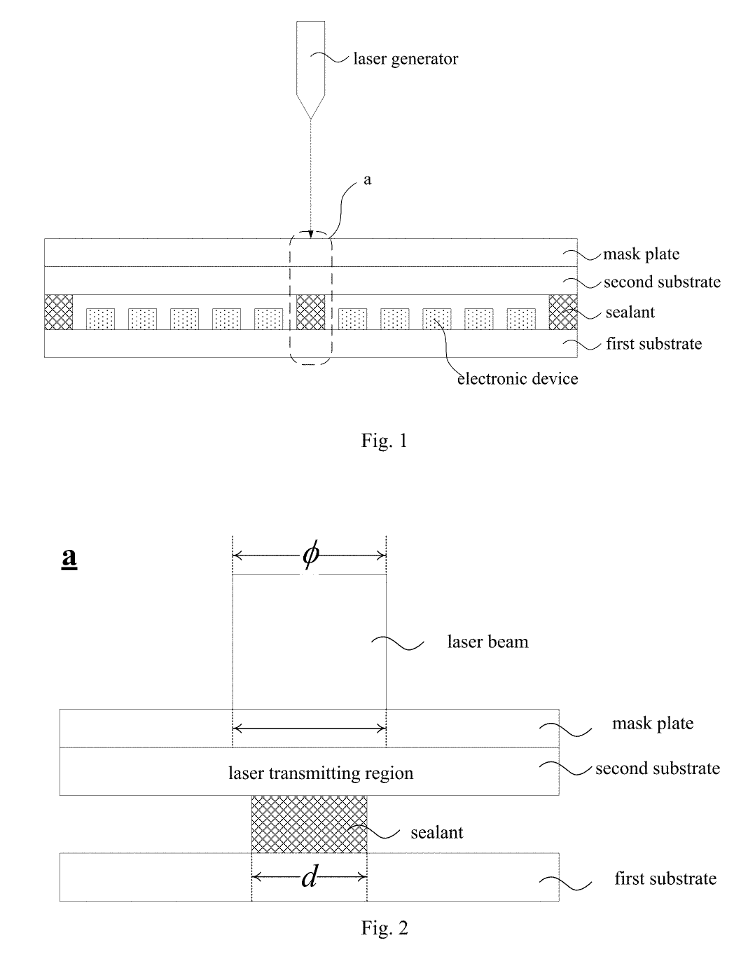

### REFERENCE NUMERALS

01: mask plate; 11: laser blocking region; 111: second main body; 112: diffusing surface; 113: light absorbing layer; 12: laser transmitting region; 121: first main body; 02: panel to be encapsulated; 20: sealant; 21: encapsulating region; 22: device region; 31: first substrate; 32: second substrate.

### DETAILED DESCRIPTION

The technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

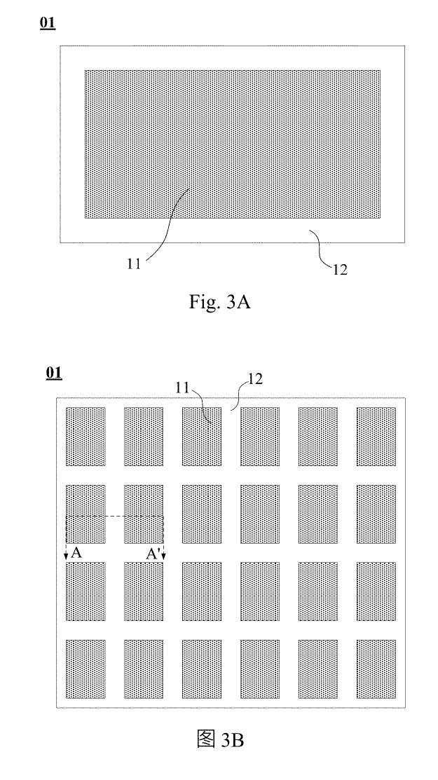

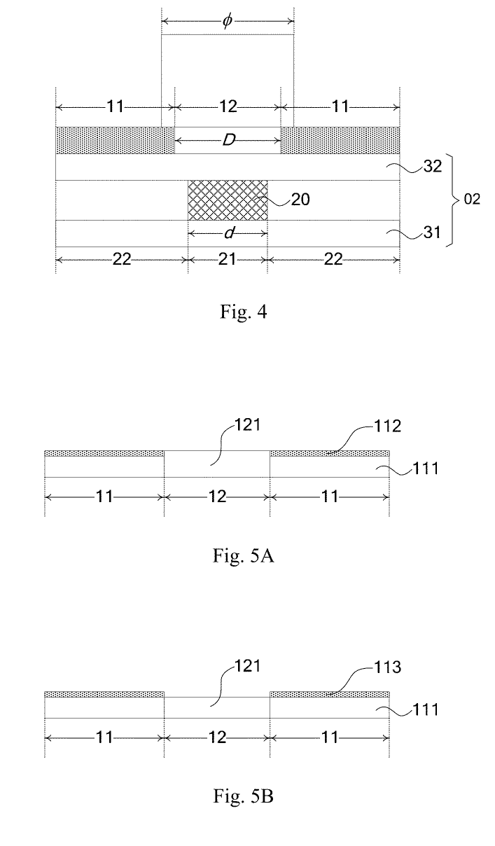

An embodiment of the disclosure provides a mask plate 01 for laser irradiation. As illustrated in FIGS. 3A and 3B, the mask plate 01 includes a laser blocking region 11 and a laser transmitting region 12 surrounding the laser blocking region 11.

According to the embodiment of the disclosure, as illustrated in FIG. 4, upon placing the mask plate 01 onto a panel 02 to be encapsulated, the laser transmitting region 12 corresponds to a encapsulating region 21 of the panel 02 to be encapsulated, and the laser blocking region 11 corresponds to a device region 22 surrounded by the encapsulating region 21 on the panel 02 to be encapsulated; and along a direction perpendicular to a surface of the mask plate 01 (not illustrated in FIG. 4, please refer to FIGS. 3A and 3B), a width (indicated as D hereinafter) of a cross-section of the laser transmitting region 12 is smaller than a diameter (indicated as φ hereinafter) of a light spot of the laser, and the width D of the cross-section of the laser transmitting region is larger than or equal to a width (indicated as d hereinafter) of a cross-section of the encapsulating region 21.

It should be noted that, for the mask plate provided by the embodiment of the present disclosure, the above-described laser transmitting region 12 refers to a region in the mask plate 01 where the laser having a predetermined wavelength is permitted to transmit; while the laser blocking region 11 refers to a region where the laser having the predetermined wavelength is reflected or absorbed. As used herein, the term “laser having a predetermined wavelength” refers to the laser having the predetermined wavelength of which the energy is sufficient to melt a sealant 20 within the encapsulating region 21 of the panel 02 to be encapsulated, so that the sealant 20 can be cured and hence the panel 02 can be encapsulated.

The material and width of the mask plate 01 are not particularly defined in the embodiments of the present disclosure, but provided that it allows both the laser blocking region 11 and laser transmitting region 12 achieve corresponding functions mentioned above.

In one example, a thickness of the mask plate 01 is 3 mm˜5 mm. This range of thickness allows the laser to transmit through the laser transmitting region 12 sufficiently without any energy loss of the laser beam which may be resulted by an excessively thicker mask plate.

It also should be noted that, for the panel 02 to be encapsulated, the encapsulating region 21 is a region covered by the sealant 20, while the device region 22 is a region surrounded by the encapsulating region 21.

The encapsulating region 21 of a panel 02 to be encapsulated is to encapsulate the electronic devices inside, thus a shape of the encapsulating region 21 for such panel is generally a square ring and a width of the cross-section of the encapsulating region 21 is usually equal to the width of the cross-section of the sealant 20; that is, a width of the square ring of the encapsulating region 21 illustrated in FIG. 3A. Correspondingly, for a display panel used as the panel 02 to be encapsulated, since the laser transmitting region 12 in the mask plate 01 provided by the embodiment of the disclosure corresponds to the encapsulating region 21 of the panel 02 (upon placing the mask plate 01 onto the panel 01), as illustrated in FIG. 3A, the width D of the cross-section of the laser transmitting region 12 is just consistent with the width of the square ring of the encapsulating region 21.

During practical manufacture of the display panel, in order to improve mass production, the panel 02 to be encapsulated is generally a motherboard, that is, the panel 02 to be encapsulated includes a plurality of device regions 22 arranged in an array, in which a spacing between any two adjacent device regions 22 along a row direction is the same with a spacing between any two adjacent device regions 22 along a column direction, and each of the device regions 22 is surrounded by the encapsulating region 21. Upon the motherboard is encapsulated, it may be cut into a plurality of smaller panels with the same size. As a result, a shape of the encapsulating region 21 is just a shape of a region on the motherboard except the plurality of device regions 22. In such case, referring to FIG. 4, the width d of the cross-section of the sealant 20 within the encapsulating region 21 is just a width between any two adjacent device regions 22 along a row direction or a column direction.

Considering that in actual mass production the panel 20 to be encapsulated is usually the above-described motherboard having a plurality of device regions 22 arranged at same spacing, in an example, the mask plate 01 provided by the embodiment of the present disclosure includes plural laser blocking regions 11 disposed in one-to-one correspondence with the plural device regions 22, while the laser transmitting region 12 is the region on the mask plate 01 except the laser blocking region 11; and the width of the cross-section of the laser transmitting region 12 is the width between any two adjacent laser transmitting regions 12 along the row direction or the column direction. In this way, since the width D of the cross-section of the laser transmitting region 12 is larger than or equal to the width d of the cross-section of the encapsulating region 21 along the direction perpendicular to the mask plate 01, the laser beam can be transmitted through the laser transmitting region 12 to sufficiently irradiate the sealant 20 within the encapsulating region 21 to ensure that the sealant 20 can be melted and hence cured by sufficiently absorbing the laser, so that the panel 02 is encapsulated. Furthermore, as a result of the width D of the cross-section of the laser transmitting region 12 being smaller than the diameter φ of a light spot of the laser along the direction perpendicular to the surface of the mask plate 01, when the panel 02 to be encapsulated is irradiated by the laser transmitted through the mask plate 01, the laser blocking region 11 outside the laser transmitting region 12 can block the laser which would irradiate the regions outside the encapsulating region 21, so as to prevent the energy of the laser from being delivered to the electronic devices in the device region closer to edges of the encapsulating region 21. Therefore, for design of the panel 02 to be encapsulated, the electronic devices in the device region 22 can be arranged to be closer to the encapsulating region 21 to achieve narrow frame and further improve the utilization of the substrate in the panel 02 to be encapsulated.

In one example, along the direction perpendicular to the surface of the mask plate 01, the width D of the cross-section of the laser transmitting region 12 is larger than the width d of the cross-section of the encapsulating region 21 by 0.02 mm˜0.1 mm, so that the sealant 20 can absorb the light energy of the laser sufficiently without considerably increasing a diameter of the light spot of the laser, thereby improving the utilization of the laser beam.

In the case where the panel 02 to be subjected to laser encapsulation is an OLED display panel by way of example, when a conventional mask plate is used, a safety area is required to be reserved between the electronic devices and the encapsulating region to avoid the electronic devices inside the display panel to be burned by the laser beam with an extremely high transient temperature; as a result, a frame of the encapsulated OLEF display panel usually has a width reaching 1.7 mm˜1.8 mm. As a comparison, when the OLED display panel is subjected to laser encapsulation by using the mask plate 01 provided by the embodiments of the present disclosure, the width of the frame of the encapsulated OLEF display panel can be decreased to 1.3 mm˜1.5 mm because the laser blocking region 11 blocks the laser irradiating both sides of the sealant 20, which significantly reduces the width of the encapsulated display panel and improves the display effect thereof, thereby further reducing the cost.

As further development of the above technical solution, the present disclosure recognizes that: the laser that is to irradiate both sides of the encapsulating region 21 but blocked by the laser blocking region 11 outside the laser transmitting region 12 may be reflected upwards to irradiate a surface of a laser generator emitting the laser, and damage a fiber in the laser generator.

In view of this, as illustrated in FIG. 5A, an embodiment of the present disclosure provides a mask plate 01 including: a first main body 121 located at the laser transmitting region 12, wherein the first main body 121 is made of transparent material which allows laser to transmit therethrough; and a second main body 111 located at the laser blocking region 11, wherein a surface of the second main body 111 is a diffusing surface 112.

In this embodiment, it's noted that, firstly, the above-mentioned transparent material can be any one of glass, quartz, acrylic and other materials having high transmittance to most of laser; the diffusing surface 112 can be an optical surface which can reflect the laser irradiating thereon and is obtained through processing the surface of the second main body 111 by, for example, sand blasting method.

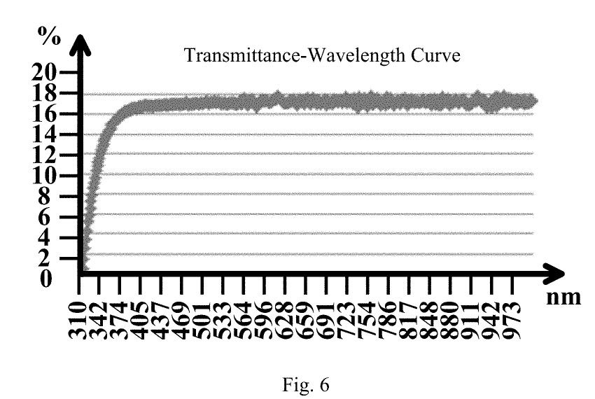

Secondly, when an upper substrate and a lower substrate of the panel 02 to be encapsulated both are made of glass, a better sealing effect can be obtained by using Frit, which can absorb infrared laser having a wavelength of 810 nm˜1000 nm at relatively higher efficiency. Therefore, when the wavelength of the laser as used for encapsulation is 810 nm˜1000 nm, a haze of the diffusing surface 112 of the mask plate according to the embodiment of the disclosure is 40%˜90%. Haze is a parameter which characterizes degree of diffusion. As illustrated in FIG. 6, given that the haze of the diffusing surface is 65%, by way of example, the transmittance of the laser with a wavelength of 310 nm˜973 nm upon irradiating on the diffusing surface 112 will be less than 20%, that is, 80% of the laser is scattered off, which avoids the reflected laser to damage the laser generator. Furthermore, the diffusing surface 112 can scatter off most of the laser irradiating thereon, thus the light energy of laser absorbed by the materials of the devices inside the panel 02 to be encapsulated is effectively decreased and an environment temperature surrounding the devices is reduced, so as to prevent the devices inside the panel 02 from cracked due to higher environment temperature.

Thirdly, the diffusing surface 112 of the second main body 111 can be, for example, located at the side of the mask plate 01 closer to the panel 02 to be encapsulated, or located at the side of the mask plate 01 far away from the panel 02 to be encapsulated. Here, considering that the mask plate 01 itself has a certain thickness, if the diffusing surface 112 is located at the side of the second main body 111 closer to the panel 02, the diffusion of the laser irradiating the diffusing surface 112 may affect the transmission of the laser at the laser transmitting region 12 surrounding the diffusing surface 112. Therefore, in one example of the embodiment, the diffusing surface 112 is located at the side of the second main body 111 far away from the panel 02 to be encapsulated.

Fourthly, in one example, the second main body 121 and the first main body 111 are formed integrally, in order to simplify the manufacturing process of the mask plate 01.

According to the embodiments of the present disclosure, in the case where both of the second main body 121 and the first main body 111 are made of glass, the above-mentioned diffusing surface 112 with a haze of 40%˜90% can be obtained by performing a sand-blasting method to a corresponding surface of the second main body 121 by using fine sands having an average diameter of 0.1 mm˜0.2 mm. The method is advantageous in low cost, low environment pollution and the like.

Alternatively, as illustrated in FIG. 5B, another embodiment of the present disclosure provides a mask plate 01, including: a first main body 121 which is located at the laser transmitting region 12, wherein the first main body 121 is made of transparent material which allows laser to transmit therethrough; and a second main body 111 located at the laser blocking region 111, wherein a surface of the second main body 111 is a light absorbing layer 113.

In this embodiment, it's noted that, firstly, the above-mentioned transparent material can be any one of glass, quartz, acrylic and other materials having high transmittance to most of laser; the above-mentioned light absorbing layer can be made of light absorbing metal (for example, Mo, Cr, Cu etc.) and black organic coating or the like (for example, phthalocyanine, 2,3-naphthalocyanine, substituted indanthrone, and some high substituted anthraquinone etc.).

Secondly, the light absorbing layer 113 is located at a surface of the second main body 111. For example, it can be located at a side of the mask plate 01 closer to the panel 02 to be encapsulated, or located at a side of the mask plate 01 far away from the panel 02 to be encapsulated. Here, considering that the light absorbing layer 113 is located at the side of the second main body 111 closer to the panel 02, it may be increased in its temperature upon absorbing the laser irradiating thereon and affect the panel 02 closer thereto. Therefore, in one example of the embodiment, the light absorbing layer 113 is located at the side of the second main body 111 far away from the panel 02 to be encapsulated, so that most of the laser irradiating the light absorbing layer 113 can be absorbed, thus the light energy of laser absorbed by the materials of the devices inside the panel 02 to be encapsulated is effectively decreased and an environment temperature surrounding the devices is reduced, so as to prevent the devices inside the panel 02 from cracked due to higher environment temperature.

Thirdly, in one example, the second main body 121 and the first main body 111 are formed integrally, in order to simplify the manufacturing process of the mask plate 01.

According to the embodiment of the present disclosure, in the case where the light absorbing layer is made of light absorbing metal such as Mo, the above-mentioned light absorbing layer 113 can be deposited on the surface of the second main body 111 by a coating method.

In addition, an embodiment of the disclosure further provides a method of laser encapsulation using the above-mentioned mask plate. The method includes: placing the mask plate onto the panel to be encapsulated, so that the laser blocking region corresponds to the device region of the panel to be encapsulated and the laser transmitting region corresponds to the encapsulating region of the panel to be encapsulated; and allowing the laser to transmit through the mask plate to irradiate a sealant in the encapsulating region of the panel to be encapsulated, so that the sealant is cured.

Referring to FIG. 4, allowing the laser to transmit through the mask plate 01 provided by the foregoing embodiments to irradiate a sealant 20 in the panel 02 to be encapsulated, so that the sealant 20 is cured. The sealant 20 is located in the encapsulating region 21 of the panel 02 to be encapsulated.

Here, the sealant 20 is located in the encapsulating region 21 between the first substrate 31 and the second substrate 32 which are assembled together.

With reference to the foregoing description of the mask plate 01, upon placing the mask plate 01 onto the panel 02 to be encapsulated, as a result of the width D of the cross-section of the laser transmitting region 12 being larger than or equal to the width d of the cross-section of the encapsulating region 21 along the direction perpendicular to the mask plate 01, the laser beam can be transmitted through the laser transmitting region 12 to sufficiently irradiate the sealant 20 in the encapsulating region 21 to ensure that the sealant 20 can be melted and hence cured by sufficiently absorbing the laser, so that the panel 02 is encapsulated. Furthermore, as a result of the width D of the cross-section of the laser transmitting region 12 is smaller than the diameter φ of the light spot of the laser along the direction perpendicular to the surface of the mask plate 01, when the panel 02 to be encapsulated is irradiated by the laser transmitted through the mask plate 01, the laser blocking region 11 outside the laser transmitting region 12 can block the laser which would irradiate the regions outside the encapsulating region 21, so as to prevent the energy of the laser from being delivered to the electronic devices in the device region 22 closer to edges of the encapsulating region 21. Therefore, for design of the panel 02 to be encapsulated, the electronic devices in the device region 22 can be arranged to be closer to the encapsulating region 21 to achieve narrow frame and further improve the utilization of the substrate in the panel 02 to be encapsulated.

Considering the sealant is generally made of Frit, in one example, infrared laser having a wavelength of 810 nm˜1000 nm can be used for its relatively higher absorption efficiency with respective to Frit.

It is to be noted that, all the accompanying drawings of the present disclosure are brief diagrams illustrating the above-mentioned mask plate and method of laser encapsulation using the mask plate to clearly and definitely explain the structures relevant to the inventive concepts in the technical solutions, with other structures irrelevant or well-known in the art omitted for clarity.

The foregoing are merely specific embodiments of the disclosure, but not limitative to the protection scope of the present disclosure. Therefore, the protection scope of the disclosure should be defined by the accompanying claims.

The present disclosure claims the benefits of Chinese patent application No. 201510284585.9, which was filed with the SIPO on May 28, 2015 under the title of “MASK PLATE FOR LASER IRRADIATION AND METHOD OF LASER ENCAPSULATION” and is fully incorporated herein by reference as part of this application.

1. A mask plate for laser irradiation, comprising a laser blocking region and a laser transmitting region surrounding the laser blocking region, wherein
the laser blocking region is configured to block laser having a predetermined wavelength; and
the laser transmitting region is configured to allow the laser having the predetermined wavelength to transmit there-through,
wherein along a direction perpendicular to a surface of the mask plate, a width of a cross-section of the laser transmitting region is smaller than a diameter of a light spot of the laser having the predetermined wavelength.

2. The mask plate of claim 1, wherein upon the mask plate being placed onto a panel to be encapsulated, the laser transmitting region corresponds to an encapsulating region of the panel to be encapsulated, and the laser blocking region corresponds to a device region surrounded by the encapsulating region of the panel to be encapsulated.

3. The mask plate of claim 1, wherein
the mask plate comprises plural laser blocking regions, and
upon the mask plate being placed onto a panel to be encapsulated, the plural laser blocking regions correspond to plural device regions arranged at an array in the panel to be encapsulated, and the laser transmitting region corresponds to a region except the device regions in the panel to be encapsulated.

4. The mask plate of claim 1, further comprising:
a first main body which is located at the laser transmitting region and is made of transparent material; and
a second main body which is located at the laser blocking region, wherein a surface of the second main body is a diffusing surface.

5. The mask plate of claim 4, wherein
a wavelength of the laser is 810 nm˜1000 nm; and
a haze of the diffusing surface is 40%˜90%.

6. The mask plate of claim 4, wherein
upon the mask plate being placed onto a panel to be encapsulated, the diffusing surface of the second main body located at the laser blocking region is located at a side of the second main body far away from the panel to be encapsulated.

7. The mask plate of claim 1, further comprising:
a first main body, which is located at the laser transmitting region and is made of transparent material; and
a second main body, which is located at the laser blocking region, wherein a surface of the second main body is a light absorbing layer.

8. The mask plate of claim 7, wherein
upon the mask plate being placed onto a panel to be encapsulated, the light absorbing layer of the second main body located at the laser blocking region is located at a side of the second main body far away from the panel to be encapsulated.

9. The mask plate of claim 4, wherein the transparent material comprises any one of glass, quartz and acrylic.

10. The mask plate of claim 4, wherein
the second main body and the first main body are integrally formed.

11. The mask plate of claim 1, wherein
upon the mask plate being placed onto a panel to be encapsulated, a width of the cross-section of the laser transmitting region is larger than or equal to the width of a cross-section of the encapsulating region along a direction perpendicular to the surface of the mask plate.

12. The mask plate of claim 11, wherein, the width of the cross-section of the laser transmitting region is larger than the width of the cross-section of the encapsulating region by 0.02 mm˜0.1 mm.

13. The mask plate of claim 1, wherein, a thickness of the mask plate is 3 mm˜5 mm.

14. A method of laser encapsulation using a mask plate of claim 1, comprising:
placing the mask onto the panel to be encapsulated, so that the laser blocking region corresponds to the device region of the panel to be encapsulated and the laser transmitting region corresponds to the encapsulating region of the panel to be encapsulated; and
allowing the laser to transmit through the mask plate to irradiate a sealant located in the encapsulating region of the panel to be encapsulated, so that the sealant is cured.

15. The method of claim 14, wherein
the sealant is made of silicon sealant; and
a wavelength of the laser is 810˜1000 nm.

16. The mask plate of claim 2, further comprising:
a first main body which is located at the laser transmitting region and is made of transparent material; and
a second main body which is located at the laser blocking region, wherein a surface of the second main body is a diffusing surface.

17. The mask plate of claim 16, wherein
upon the mask plate being placed onto a panel to be encapsulated, the diffusing surface of the second main body located at the laser blocking region is located at a side of the second main body far away from the panel to be encapsulated.

18. The mask plate of claim 16, wherein
the transparent material comprises any one of glass, quartz and acrylic.

19. The mask plate of claim 16, wherein
the second main body and the first main body are integrally formed.

20. The mask plate of claim 16, wherein
upon the mask plate being placed onto a panel to be encapsulated, a width of the cross-section of the laser transmitting region is larger than or equal to the width of a cross-section of the encapsulating region along a direction perpendicular to the surface of the mask plate.
